(19) United States
(12) Patent Application Publication
(10) Pub. No.: US 2009/0213549 A1
(43) Pub. Date: Aug. 27, 2009

(54) HEAT SINK ASSEMBLY

(75) Inventors: LEI GUO, Shenzhen City (CN); YU-HSU LIN, San Jose, CA (US); JENG-DA WU, Tu-Cheng (TW); CHIH-HANG CHAO, Tu-Cheng (TW); YANG LI, Shenzhen City (CN); LIANG-LIANG CAO, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/210,499

(22) Filed: Sep. 15, 2008

(30) Foreign Application Priority Data
Feb. 22, 2008 (CN) 200820300262.X

(51) Int. Cl. H05K 7/20

(52) U.S. Cl. 361/704

(57) ABSTRACT

A heat sink assembly includes a printed circuit board, an electronic component mounted on the printed circuit board, and a heat sink mounted on the printed circuit board for dissipating heat from the electronic component. The printed circuit board includes a heat-conduction layer. The heat sink includes a base configured to contact the heat-conduction layer, and a main body extending upward from the base configured to contact the electronic component. The cross section of the base is larger than the cross section of the main body. A plurality of fins extends from the main body.

### BACKGROUND

1. Technical Field

The present invention relates to a heat sink assembly for dissipating heat for an electronic component mounted on a printed circuit board.

2. Description of Related Art

There are many components mounted on a printed circuit board, such as a south bridge, a north bridge, and an Integrated circuit (IC). A component, such as a CPU, usually needs a heat sink for heat dissipation. A typical heat sink includes a base and a plurality of fins extending from the base. The heat sink is often mounted on the CPU with the base contacting a surface of the CPU. However, there are some components which are mounted on a PCB, such as Metal-Oxide-Semiconductor Transistor (MOST), that do not have an available heat sink to dissipate heat generated from the MOST.

Therefore, a heat sink assembly for an electronic component mounted on a PCB is desired to overcome the above described deficiency.

### BRIEF DESCRIPTION OF THE DRAWINGS

FIG. 1 is an exploded, isometric view of an embodiment of a heat sink assembly, the heat sink assembly includes a heat sink;

FIG. 2 is an isometric view of the heat sink of FIG. 1; and

FIG. 3 is an assembly view of FIG. 1.

### DETAILED DESCRIPTION OF THE EMBODIMENTS

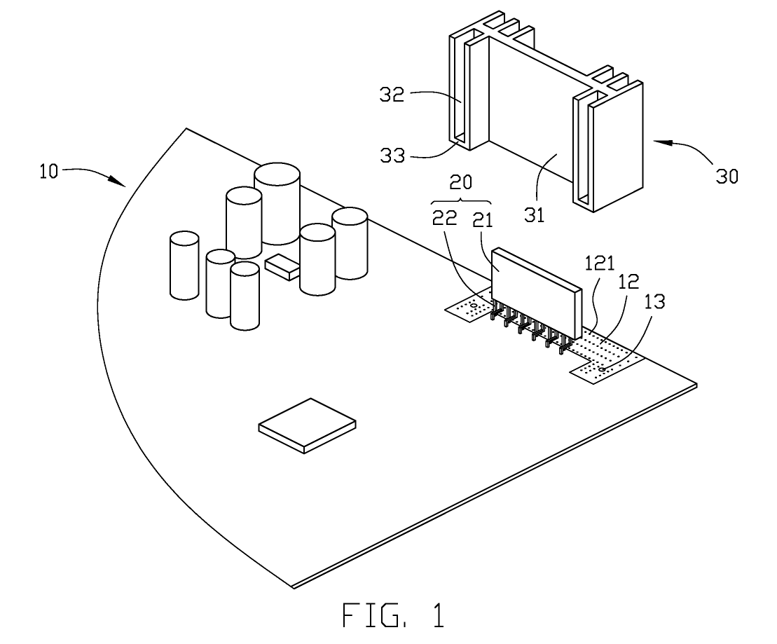

Referring to FIG. 1, a heat sink assembly includes a PCB 10, an electronic component 20 mounted on a side of the PCB 10, and a heat sink 30 for dissipating heat generated from the electronic component 20.

The electronic component 20 includes a principal body 21 and a plurality of pins 22 extending from a bottom of the principal body 21 and secured to the PCB 10. The principal body 21 may be mounted on the PCB 10 such that a large surface area is perpendicular to the PCB. The PCB 10 includes a heat-conduction layer 12, positioned on a first side of the PCB 10 near the plurality of pins 22. The heat-conduction layer 12 may be a copper foil. A plurality of heat dissipating holes 121 extend through the PCB 10 and the heat-conduction layer 12. The heat dissipating holes are configured to transfer heat from a first side of the PCB to an opposite second side of the PCB 10. A pair of securing holes 13 is defined in the PCB 10 at opposite sides of the heat-conduction layer 12.

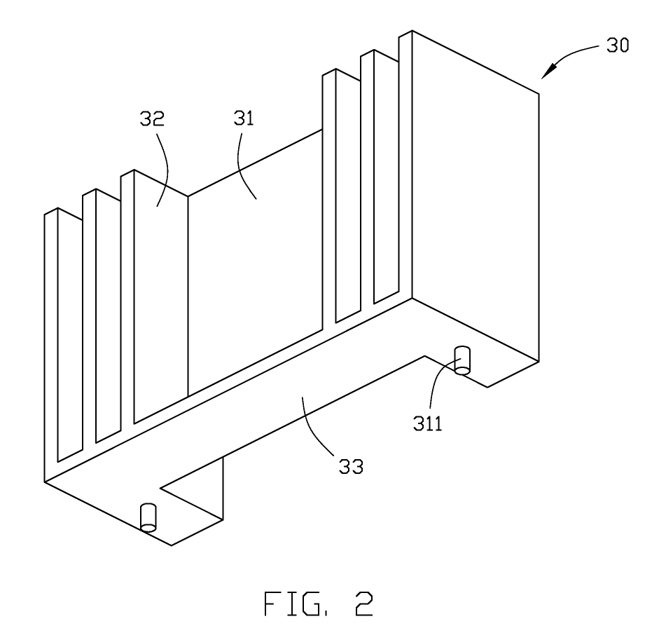

Referring also to FIG. 2, the heat sink 30 includes a base 33 and a main body 31 extending from the base 33. A plurality of parallel fins 32 extends perpendicularly from at least one surface of the main body 31. In one embodiment, A cross section of the base 33 is larger than a cross section of the main body 31. A pair of securing posts 311 extends from the bottom surface of the base 33 corresponding to the pair of securing holes 13 for mounting the heat sink 30 to the PCB 10.

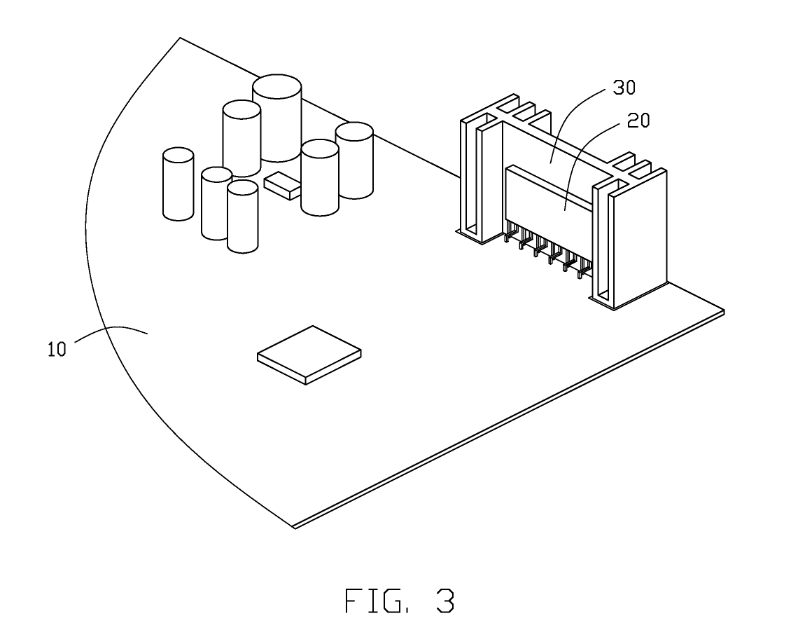

Referring also to FIG. 3, the securing posts 311 of the heat sink 30 are inserted into the securing holes 13 of the PCB 10, and secured on the PCB 10, for example, by soldering or gluing. A mating surface of the main body 31 of the heat sink 30 is in thermal communication with the principal body 21 of the electronic component 20. The base 33 of the heat sink 30 is in thermal communication with the heat-conduction layer 12.

When the electronic component 20 is in operation, heat generated from the electronic component 20 is transferred to the heat sink 30, to the base 33, and to the heat-conduction layer 12. Heat from the heat-conduction layer 12 is transferred from the first side to the second side of the PCB 10 via the heat-dissipation holes 121.

In one embodiment, a layer of a heat-production medium, such as thermal grease, may be placed between the principal body 21 of the electronic component 20 and the main body 31 of the heat sink 30.

It is to be understood, however, that even though numerous characteristics and advantages of the present embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink assembly, comprising:
a printed circuit board comprising a heat-conduction layer;
an electronic component mounted on the printed circuit board; and
a heat sink mounted on the printed circuit board and configured to dissipate heat from the electronic component, the heat sink comprising:
a base configured to contact the heat-conduction layer; and
a main body extending upward from the base and configured to contact the electronic component, wherein a cross section of the base is larger than a cross section of the main body; the main body comprising a plurality of fins extending from the main body.

2. The heat sink assembly of claim 1, wherein the base is substantially perpendicular to the main body.

3. The heat sink assembly of claim 2, wherein the plurality of fins extend from at least one surface of the main body and is substantially perpendicular to the base.

4. The heat sink assembly of claim 1, wherein the electronic component comprises:
a principal body having a surface area substantially perpendicular to the printed circuit board, wherein the surface area is thermally communicating with the main body; and
a plurality of pins extending from the principal body and secured to the printed circuit board.

5. The heat sink assembly of claim 4, wherein a layer of heat-conduction medium is positioned between the principal body and the heat sink.

6. The heat sink assembly of claim 1, wherein the heat sink further comprises two securing posts extending from the base; two securing holes are defined in the printed circuit board corresponding to the two securing posts and configured to receive the two securing posts.

7. The heat sink assembly of claim 1, wherein a plurality of heat dissipating holes is defined in the heat-conduction layer.

8. The heat sink assembly of claim 1, wherein the heat-conduction layer is a copper foil.
